(19) United States
(12) Patent Application Publication
(10) Pub. No.: US 2018/0090628 A1
(43) Pub. Date: Mar. 29, 2018

(54) P-Type solar cell with limited emitter saturation current

(71) Applicant: SolarWorld Innovations GmbH, Freiberg (DE)

(72) Inventors: Giuseppe Citarella, Chemnitz (DE); Bernd Bitnar, Bannewitz (DE)

(21) Appl. No.: 15/278,085

(22) Filed: Sep. 28, 2016

(51) Int. Cl. H01L 31/02; H01L 31/0288; H01L 31/18; H01L 31/0216

(52) U.S. Cl. CPC H01L 31/02008; H01L 31/0288; H01L 31/02167; H01L 31/1804; H01L 31/1884

(57) ABSTRACT

The current disclosure describes a p-type solar cell with back emitter with increased electrical efficiency and decreased manufacturing and material costs. According to one aspect of the present disclosure, the solar cell comprises gallium-doped silicon, closely arranged contact openings in the rear passivation layer, and physical vapor deposition application of at least one metal to create the rear contact. The front and rear contacts may be applied over a sputtered layer of transparent conducting oxide to increase transverse conductivity and permit smaller metal contacts, where desired. A plated layer of nickel or tin may be layered over the Physical Vapor Deposition-applied metal contact to create a stable, solderable surface while minimizing silver costs.

### TECHNICAL FIELD

Embodiments described herein generally relate to passivated solar cells with back emitter.

### BACKGROUND

High efficiency solar cells with a high open circuit voltage demand that their components have a very small saturation current. With current p-type Passivated Emitter Rear Contact high performance solar cells, the emitter is generally the dominant source of recombination loss. To minimize loss, it is particularly desirable to keep the saturation current of the solar cell's emitter as small as possible. Efforts to increase efficiency by reducing the emitter saturation current may be frustrated by corresponding losses of efficiency elsewhere. For example, although the saturation current can be reduced by increasing the emitter's sheet resistance, an increase in the sheet resistance results in an increase of the series resistance loss through a reduced transverse conductivity.

One method of reducing the series resistance and maintaining desirable transverse conductivity is to decrease the distance between the contact fingers on the front face of the solar cell. Yet because smaller distances between the contract fingers require greater amounts of silver, and because a smaller distance results in increased shadowing of the cell's front surface, this effort to reduce series resistance can result in greater manufacturing costs and lower light input. In light of the need to improve efficiency while taking into account the consequences of changes to the solar cell's design, modifications to the cell must strike a compromise that considers the relationship between emitter sheet resistance and the distance between the contact fingers, as well as material and manufacturing costs, and other electrical efficiencies.

### SUMMARY

In a p-type solar cell with back emitter, the emitter is located on the rear side of the p-type silicon substrate. P-type solar cells with back emitters may offer increased efficiency compared to front emitter cells. In a p-type solar cell with back emitter, factors such as the width and thickness of the front contacts, the placement of contact openings in the rear passivation layer, and the configuration of a rear contact may each contribute to the overall cell efficiency. Moreover, material and manufacture costs must be taken into account to improve electrical efficiency while maintaining commercial viability. Where possible, efforts to improve the solar cell should consider the available manufacturing technology and processes, and attempt to use equipment already available.

According to one aspect of the present disclosure, the solar cell comprises gallium-doped silicon to improve consistency and minority carrier lifetime. According to another aspect of the present disclosure, the front and/or rear contact comprises a transparent coating oxide, upon which especially thin metal contacts may be printed or placed in another way. The thin metal contacts maintain acceptable transverse connectivity without the danger of unnecessary shadowing of the solar cell. Additionally, the thin contacts reduce material costs, particularly where the metal contacts are silver.

According to another aspect of the present disclosure, laser etching or ablation is used to create very small, closely configured contact openings in the rear passivation layer. This configuration of openings permits reduced rear-surface recombination losses while maintaining the reflective advantage of the rear emitter configuration.

According to another aspect of the present disclosure, physical vapor deposition (“PVD”) is used to apply a rear metal contact, which can dramatically reduce or even eliminate the use of silver for the rear contact and thereby reduce manufacturing costs.

According to another aspect of the present disclosure, nickel may be plated on the rear of the PVD-applied rear contact to create a stable, solderable layer for electrical connectivity.

### BRIEF DESCRIPTION OF THE DRAWINGS

In the drawings, like reference characters generally refer to the same parts throughout the different views. The drawings are not necessarily to scale; rather, emphasis instead is generally placed upon illustrating the principles of the invention. In the following description, various aspects of the disclosure are described with reference to the following drawings, in which:

FIG. 1 shows a p-type rear emitter solar cell, according to an aspect of the disclosure.

FIG. 2. shows a p-type rear emitter solar cell with a solderable metalized rear layer, according to an aspect of the disclosure.

FIG. 3 shows a p-type rear emitter solar cell with front contacts printed on the surface of the silicone substrate, according to an aspect of the disclosure.

FIG. 4 shows a p-type rear emitter solar cell with a rear contact comprising a transparent conducting oxide coating and printed rear fingers, according to an aspect of the disclosure.

FIG. 5 shows a solar cell with soldered wire connections.

FIG. 6 shows a passivation layer with contact openings arranged in a matrix of dots, according to an aspect of the disclosure.

FIG. 7 shows a passivation layer with contact openings arranged in a grid, according to an aspect of the disclosure.

FIG. 8 shows one aspect of the solar cell according to the disclosure, wherein rear contacts are placed on a layer of transparent conducting oxide, according to an aspect of the disclosure.

FIG. 9 shows another aspect of the solar cell according to the disclosure, wherein the front contacts are printed on a layer of transparent conductive oxide.

FIG. 10 shows a method for manufacturing a p-type solar cell, according to an aspect of the disclosure.

### DETAILED DESCRIPTION

The following detailed description refers to the accompanying drawings that show, by way of illustration, specific details and aspect in which the present disclosure may be practiced. Other aspects may be utilized, and structural, logical, and electrical changes may be made without departing from the scope of the invention. The various aspects of this disclosure are not necessarily mutually exclusive, as some aspects of this disclosure can be combined with one or more other aspects of this disclosure to form new aspects.

Further, in this application the term “front” and “rear” are used to refer to the position of portions of the solar cell relative to the light. The front of the solar cell is the portion that faces light. The rear of the solar cell is the portion opposite the side that faces light.

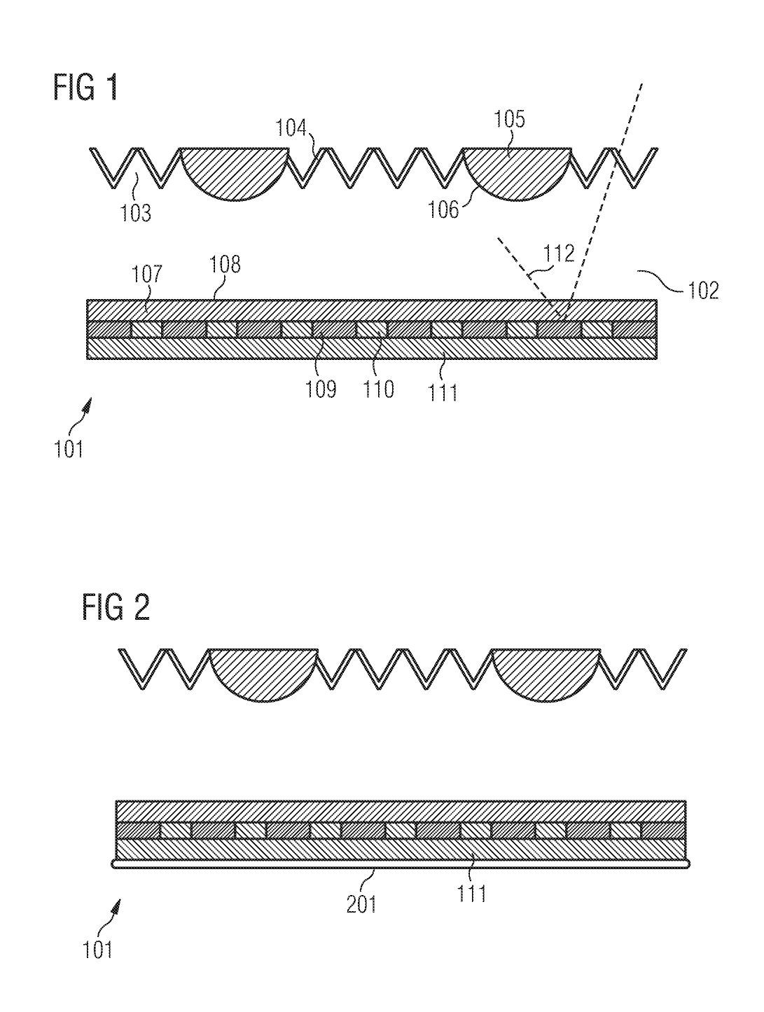

FIG. 1 shows an exemplary p-type solar cell with back emitter 101. This is a high-efficiency p-type solar cell with back emitter. The solar cell comprises a p-type silicon substrate 102. The front of the substrate comprises a textured surface 103, which reduces reflection and increases the likelihood that any reflected light will be redirected to another portion of the solar cell.

The front surface comprises a passivation layer 104. Said front passivation layer may comprise silicon nitride or silicon dioxide, or any other suitable substance. The passivation layer reduces front surface recombination, and thereby contributes to the efficiency of the cell.

The front surface further comprises at least one front contact 105. The front contact may be configured as strips or lines across the front surface of the cell. Where said front contacts appear as thin lines, they may be referred to in this disclosure as “fingers,” given their appearance resembling fingers. The front contacts may comprise silver, aluminum, copper or a stack containing silver or aluminum or copper.

The front fingers 105 may be created by screen printing Aluminum metal paste on the dielectric layer on the front of the substrate 102 and then firing the cell. During firing, the printed metallization line will etch off the underlying dielectric layer 104, and the Aluminum will come into direct contact with the silicon surface. The printed Aluminum metallization will alloy into the silicon substrate and will cool down. In this process, the front contact structure becomes situated in grooves 106 on the surface of the substrate. Alternatively, the front fingers may be created by galvanic deposition.

According to one aspect of the disclosure, the front contacts are screen-printed. They may be screen-printed with a medium comprising silver or aluminum. The front contacts may be screen printed in one layer, or they may be screen-printed in multiple layers. Said screen printed contacts in at least two layers may provide reduced resistance and/or reduced shadowing compared to contacts that are printed in a single layer.

According to one embodiment of the disclosure, the front contacts 105 are printed in long, thin lines resembling fingers, with a width of 10 μm to 300 μm. According to a second embodiment, the front contacts are 20 μm to 150 μm wide. According to a third embodiment, the front contacts are 25 μm to 90 μm wide. According to a fourth embodiment, the front contacts are 30 μm to 60 μm wide. This narrow width of the front contacts permits minimal shadowing of the silicon substrate 102. The front contacts 105 may be printed directly onto the textured silicon substrate 102 or directly onto the passivation layer 104. The front contacts 105, where screen-printed, may be fired to penetrate the passivation layer and/or to create or the bond between the contact material and the silicon substrate 102.

The rear side of the silicon substrate comprises an emitter 107. According to one aspect of the disclosure, the emitter may have a sheet resistance of greater than 200 Ω/sq. Alternatively, the emitter may have a sheet resistance of greater than 250 Ω/sq. The emitter may also have a sheet resistance of greater than 300 Ω/sq. The rear emitter is planar, rather than textured. The emitter is characterized as a high ohm emitter. The emitter has an emitter saturation current of less than 50 fA/cm² or less than 20 fA/cm².

The emitter is located at the rear surface of a p-type silicon substrate, where the substrate has been doped to create a PN junction 108. According to one aspect of the disclosure, the p-type silicon is doped with boron. According to another aspect of the disclosure, the p-type silicon is doped with gallium. In certain embodiments, a gallium-doped substrate may have a longer expected minority carrier lifetime and may result in higher efficiency of the p-type solar cell with back emitter. Minority carrier lifetime is defined as the minority carrier lifetime of the bulk of the substrate. To measure the minority carrier lifetime of the substrate, the surfaces of the substrate need to be well passivated. This way it is assured that the measurement of the lifetime results in the minority carrier lifetime of the bulk of the substrate and is not limited by lifetime reducing effects at the surfaces of the substrate. According to another aspect of the disclosure, after creating the emitter, select positions of the rear surface of the p-type silicon substrate 102 will be highly doped, which will result in a selective emitter. The low doping profile permits a very low emitter saturation current, whereas the highly doped portions can be used for applying contacts. Selective doping is achieved by applying a doping medium only to portions of the rear surface of the silicon substrate or by applying a doping medium to the whole rear surface and driving the dopant into the substrate on select portions, only. The doping medium may be a dielectric layer, wherein said dielectric layer may comprise phosphorous doped silicon nitride (SiN:P).

A rear passivation layer 109 is placed on the rear side of the emitter. The rear passivation layer 109 is a dialectic layer. The rear passivation layer 109 may be reflective. Where the rear passivation layer is reflective, this may increase the efficiency of the solar cell by reflecting unabsorbed light 112 toward the front of the cell, thereby offering an additional opportunity for the light to be turned into electrical energy. Furthermore, the reflection of light from the passivation layer reduces the light that travels to the rear contact. Where no reflective passivation layer is present, light that reaches the rear contact may be absorbed by the rear contact and turned into heat. This absorption is generally undesirable, as it may decrease the solar cell's efficiency. Accordingly, according to one aspect of the current disclosure, a reflective rear passivation layer is used to increase cell efficiency by reflecting unconverted light toward the front of the cell. The rear passivation layer contains openings 110, which permit contact between the rear contact and the emitter. These openings may be created by etching or laser ablation.

A rear contact 111 is found on the rear side of the rear passivation layer. This rear contact may comprise a full-surface layer of metal, which can be applied with a PVD process. Alternatively, the rear contact may comprise a layer of transparent conducting oxide (“TCO”), upon which a metalized layer may be placed.

FIG. 2. shows a solar cell 101 as demonstrated in FIG. 1, above, with an additional, full-surface, metal layer on the rear of the cell 201. The full-surface layer 201 may comprise nickel. The full-surface layer may be plated or sputtered on the rear surface of the rear contact 110. This metal layer may provide a solderable surface on the rear of the solar cell, where the rear contact 111 is not directly solderable. According to one aspect of the current disclosure, the rear contact may comprise a layered stack of silver and nickel. This silver and nickel stack may be applied directly to the passivation layer, or it may be applied to a TCO layer that is applied to the passivation layer. According to another aspect of the current disclosure, the rear contact may comprise a layered stack of aluminum and nickel. Similarly, this aluminum and nickel stack may be applied directly to the passivation layer, or it may be applied to a TCO layer that is applied to the passivation layer. According to another aspect of the current disclosure, a copper and nickel stack may be applied to a TCO layer that is applied to the passivation layer.

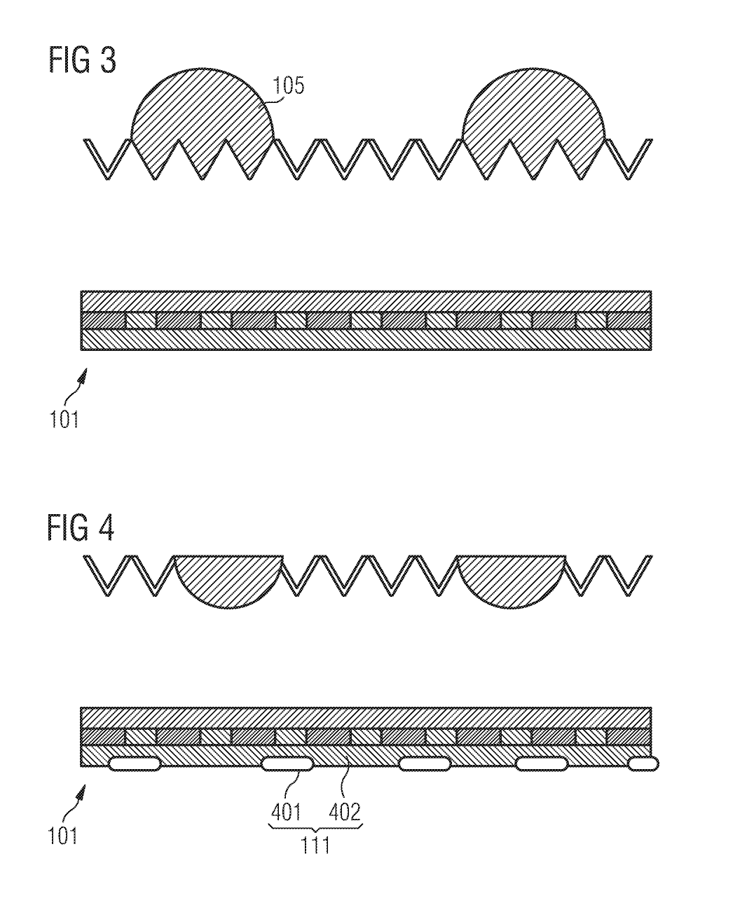

FIG. 3 shows an embodiment of the solar cell, where the front contacts 105 are printed on top of the solar cell. This may be achieved by printing the metallization paste on the passivation layer and letting the metal paste fire through the passivation layer during a subsequent firing process. Alternatively, this may be achieved by removing the front passivation layer where the front contacts are to be printed or plated with a galvanic process. Alternatively, this may be achieved where the front passivation layer is not applied to the areas where the front contacts are placed.

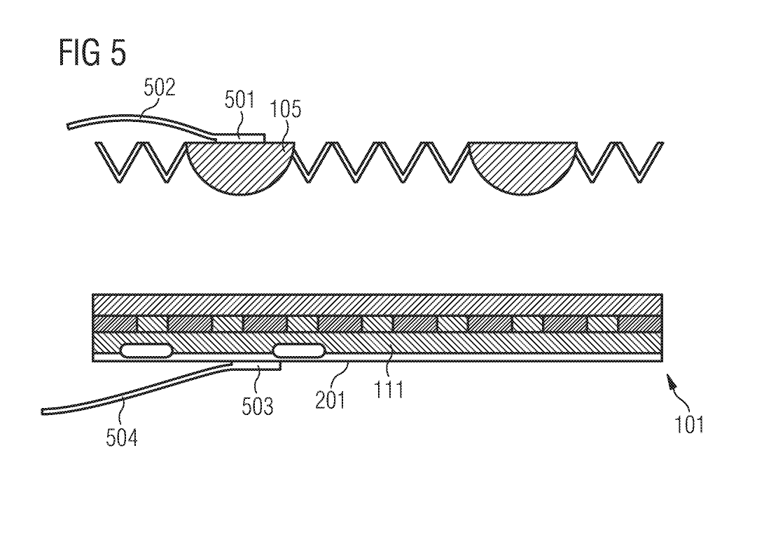

FIG. 4 shows an embodiment where metal strips or fingers 401 are printed on the rear side of a transparent coating oxide 402. In this embodiment, the transparent coating oxide 402 and the metal strips or fingers 402 are the rear contact 111. According to an aspect of the disclosure, the metal fingers 401 are solderable.

FIG. 5 shows the solar cell 101 with wires for transfer of electrical current. A front solder joint 501 attaches a front wire 502 to the front contact 105. A rear solder joint 503 attaches a rear wire 504 to a solderable metal layer 201 on the rear contact 111.

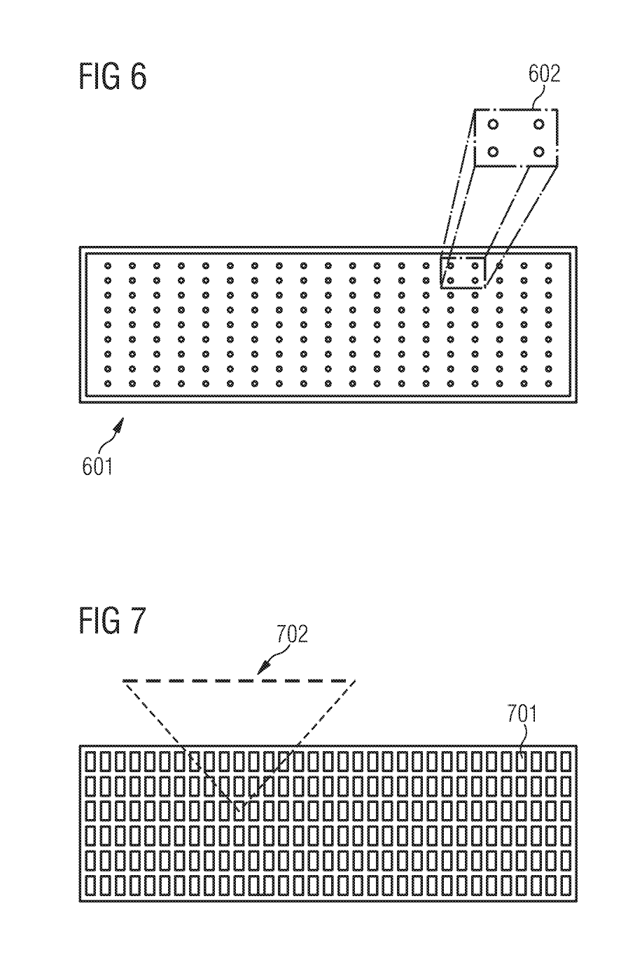

FIG. 6 shows an embodiment of the rear passivation layer openings 601, wherein the openings comprise a matrix of dots 602. The rear passivation layer may contain openings in a variety of configurations. These openings are created by removing portions of the rear passivation layer to create openings for contact between the emitter and the rear contact. In one embodiment, the contact openings 109 are less than 1200 μm apart. In another embodiment, the contact openings 109 are less than 900 μm apart. In another embodiment, the contact openings 109 are less than 500 μm apart. In another embodiment, the contact openings 109 are less than 300 μm apart. The close proximity of the contact openings maintains transverse conductivity and thereby limits loss.

FIG. 7 shows another embodiment of the rear passivation layer openings, wherein the rear passivation layer openings are linear 701. Said linear openings may comprise vertical lines, horizontal lines, or vertical and horizontal lines. The lines may be continuous or may contain interruptions. The lines with interruptions may resemble a dashed line 702. The presence of such a line, whether continuous or dashed, demarcates the presence of a contact opening. Where the lines are continuous, the distance between the lines is the distance between the contact openings. Where the lines have interruptions, however, the size of the interruptions is the size of the contact openings, and the distance between the interruptions is the distance between the contact openings. According to one embodiment of the disclosure, the linear openings are dashed, and the distance between the dashes is less than 1200 μm.

In one embodiment, the rear passivation layer openings, and thereby the corresponding front contacts, may be arranged in a grid, which is the specific arrangement shown in 701. The grid comprises a series of horizontal and vertical lines to form a series of squares or rectangles. The grid of rear contracts corresponds to a grid of openings in the rear passivation layer.

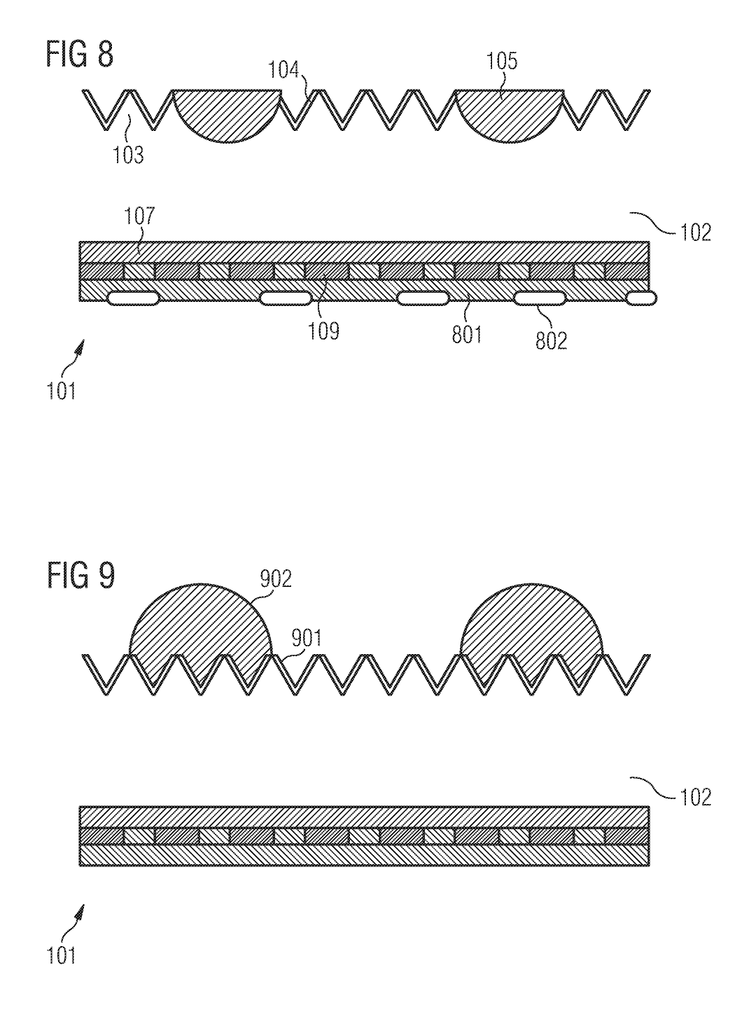

FIG. 8 shows an alternative embodiment, where the rear contacts are printed on a layer of TCO 801. In this embodiment, the rear passivation layer 109 contains openings as otherwise described, and a TCO 801 is placed on the rear side of the rear passivation layer. The openings in the rear passivation layer permit conductivity between the rear side of the substrate and the TCO 801. TCO-mounted metal contacts 802 can be placed on the surface of the TCO, as shown in 801 These metal contacts can be lines, grids, or fingers. Alternatively, the metal contacts may be a full surface contact that is then placed over the TCO layer.

In this embodiment, the TCO is applied via sputtering. Because sputtering, rather than screen printing, is used, the resulting TCO layer has a higher degree of flexibility than a screen-printed layer. With a TCO layer, it is also possible for the TCO to contact lightly-doped Silicon surfaces. As will be described below, it also allows for the creation of a bifacial solar cell.

Front Passivation and Metal Contacts

FIG. 9 shows an embodiment of the current disclosure, wherein the front side is covered with a dielectric layer 901 serving as a passivation and antireflection layer. The metallization paste 902 is printed on the passivation layer. In a subsequent firing step, the metallization paste 902 fires through the passivation layer 901, thereby creating direct contact between the metallization paste 902 and the substrate 102.

A front passivation layer 104 may be applied between the front surface of the silicon substrate 102 and the front contacts 105. In order to maintain electrical connectivity, the front passivation layer is not present where the front contacts abut the silicon substrate 106. To achieve a connection between the front contacts and the silicon substrate, the front passivation layer may be first applied to the entire front surface and then removed in part, to accommodate the front contacts. Alternatively, the metallization paste can remove a portion of the passivation layer during firing, thereby coming into direct contact with the substrate.

In one embodiment, the front contacts comprise an aluminum and silicon alloy. This can be achieved by screen printing an aluminum paste on some regions of the front surface, where the dielectric layer has been removed. When firing, the aluminum paste will alloy with the silicon, thereby forming an eutectic compound. The remaining aluminum, which did not mix into the compound, can be etched back to reduce the thickness of the fingers. In this case, the thickness of the fingers is mainly determined by the thickness of the opening in the dielectric layer, which allows the fingers to be extremely thin. According to one aspect of the Disclosure, the fingers can be created in a width between 30 μm and 60 μm, and with a correspondingly reduced shadowing effect.

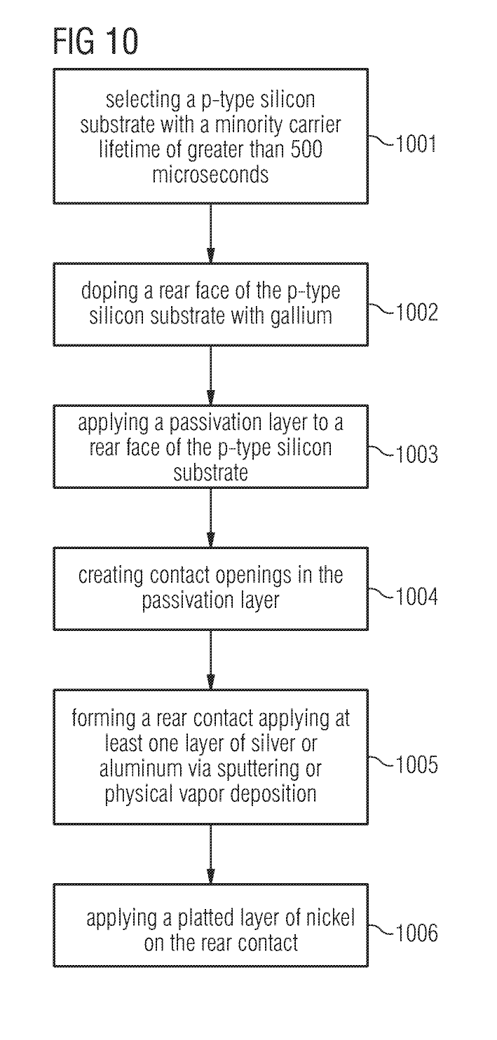

FIG. 10 shows a method for manufacturing a p-type solar cell, comprising selecting a p-type silicon substrate with a minority carrier lifetime of greater than 500 microseconds 1001; doping a rear face of the p-type silicon substrate with phosphorous 1002; applying a passivation layer to a rear face of the p-type silicon substrate 1003; creating contact openings in the passivation layer 1004; forming a rear contact applying at least one layer of silver or aluminum via sputtering or physical vapor deposition 1005; and applying a plated layer of nickel on the rear contact 1006.

The Rear Contact/Metallization

In one embodiment, the rear contact comprises silver. In a second embodiment, the rear contact comprises aluminum. The rear contact must comprise a substance that is capable of conducting current. This may be a metal or a TCO. Such a TCO may be ZnO.

The rear contact may be applied via PVD. One acceptable method of PVD for application of the rear contact is sputtering. The application of the rear contact by sputtering allows the rear contact to be applied in an extremely thin layer. In one embodiment, the rear contact is 300 nm thick. In a second embodiment, the rear contact is 200 nm thick. In a third embodiment, the rear contact is 100 nm thick.

Application of the rear contact via sputtering uses less metal and may therefore be less expensive than the traditional method of screen-printing a rear contact. This results in decreased materials costs for each wafer produced pursuant to this method.

Where the rear contact is applied via sputtering, a nickel layer may be plated or sputtered on the sputtered rear contact layer. The sputtered rear contact is not solderable, and therefore where a soldering joint is desired, additional structure must generally be applied to the rear contact to create a solderable area. In one embodiment, a nickel layer is plated or sputtered on the rear of the rear contact to provide a solderable surface.

The plated or sputtered nickel coating may provide a cost advantage over silver. Because nickel is substantially less expensive than silver, a nickel layer is less expensive than adding silver to create a solderable area. Even full-surface nickel plating is likely to be less expensive than creating a modest solderable areas with silver.

According to one embodiment, the solar cell is monofacial. The monofacial nature of the solar cell results at least from the rear contact creating an opaque surface. Within this embodiment, the thickness of the rear contact coating must be sufficient to create an opaque layer.

Alternatively, according to another embodiment, the rear contact may be an aluminum layer. This aluminum layer may be applied directly to the rear passivation layer once the passivation layer is opened at the contacting areas. Alternatively, the aluminum layer can be applied on a TCO layer, which is applied directly to the passivation layer, once the passivation layer is opened at the contacting areas. This latter embodiment, comprising a TCO layer covered by an aluminum layer may, under some circumstances, be advantageous, since a strong electrical contact results from the TCO layer on top of the wafer surface, and since the aluminum layer offers high conductivity to conduct the current from the solar cell.

In another embodiment, the full-surface layer 201 may comprise tin. The full-surface tin layer may be plated or sputtered on the rear surface of the rear contact 110. This metal layer may provide a solderable surface on the rear of the solar cell, where the rear contact 111 is not directly solderable.

In another embodiment, a full surface metal rear contact is applied over a full surface TCO. This metal layer may be plated or applied via PVD. Said metal layer may comprise aluminum or silver. Because of the substantial difference in cost between silver and aluminum, this embodiment comprising a layer of TCO which is then covered by a layer of aluminum or nickel may provide a cost savings over silver. Alternatively, where the rear contact comprises a thin layer of silver that is applied by PVD, and this thin layer of silver is then covered by an additional layer of metal, such as aluminum, this allows for minimal use of silver and results in a corresponding decrease in material costs. An additional layer of nickel would provide a good solderability of the cell with contact ribbons.

TCO Coating With Potentially Bifacial Structure

In an alternative embodiment, the solar cell is a bifacial solar cell. In this embodiment, the solar cell's rear contact is a full surface layer of a TCO, upon which solderable metal contacts are either printed or attached. The solderable metal contacts may comprise silver, aluminum or nickel. The printed contacts may be arranged in horizontal lines, vertical lines, fingers, or a grid. Any arrangement of printed contacts in this embodiment must leave a portion of the rear face of the solar cell where light can pass. Where the font face and the rear face are at least partially transparent and thereby permit light to strike the corresponding silicon substrate or emitter, the cell is bifacial.

Selective Doping

In a further embodiment, the emitter may be selectively doped. This selective doping may be achieved through the use of laser ablation. The laser ablation results in activation of electrically inactive phosphorous through a local laser heating. Contact openings are created in the rear passivation layer though a green or a red laser. The green or red laser ablates portions of the rear passivation layer to create contact opening while locally increasing the temperatures in the ablation layer at the ablation sites. The increased temperatures result in in situ doping.

Alternatively, selective doping can occur through the local recovery of doping materials from a doped dielectric layer. This doped dielectric layer may comprise silicon nitride doped with phosphorous. This method results in a selective emitter. The selective emitter reduces contact recombination by reducing the portions of the silicon substrate that are doped to create an emitter.

The following examples pertain to further embodiments. In Example NL, there is disclosed a p-type passivated solar cell with back emitter, comprising a p-type silicon substrate with a minority carrier lifetime of greater than 500 microseconds; a planar emitter on the rear side of the silicon substrate, where the emitter has a sheet resistance of greater than 200 ohms/square; a passivation layer on a rear side of the emitter; and a rear contact on a rear side of the passivation layer.

In Example 1, as described with reference to the figures, there is disclosed a p-type solar cell with back emitter, comprising a p-type silicon substrate with a minority carrier lifetime of greater than 500 microseconds; a planar emitter on the rear side of the silicon substrate; a passivation layer on a rear side of the emitter, the passivation layer having contact openings to permit contact between the emitter and a rear contact, where the distance between contact openings is less than 1200 μm; and where the rear contact is on a rear side of the passivation layer.

In Example 2, there is disclosed, as described with reference to the figures, a p-type solar cell with passivated front and rear side, comprising a p-type silicon substrate with a minority carrier lifetime of greater than 500 microseconds; a planar emitter on the rear side of the silicon substrate where the emitter has a sheet resistance of greater than 200 ohms/square; a passivation layer on a rear side of the emitter; and the rear contact on a rear side of the passivation layer, where the rear contact is applied via PVD.

In Example 3, the emitter of Examples 1, 2, or 3 is disclosed, wherein the emitter has a sheet resistance of greater than 200 Ohm/sq.

In Example 4, the emitter of Examples 1, 2, or 3 is disclosed, wherein the emitter has a sheet resistance of greater than 250 Ohm/sq.

In Example 5, the emitter of Examples 1, 2, or 3 is disclosed, wherein the emitter has a sheet resistance of greater than 300 Ohm/sq.

In Example 6, the emitter of Examples 1, 2, or 3 is disclosed, wherein the emitter is planar.

In Example 7, the emitter of Example 6 is disclosed, wherein the emitter is not textured.

In Example 8, the solar cell in Examples 1, 2, or 3 is disclosed, wherein the solar cell is a high efficiency cell.

In Example 9, the solar cell in Examples 1, 2, or 3 is disclosed, wherein the solar cell is a p-type cell.

In Example 10, the solar cell in Example 9 is disclosed, wherein the solar cell comprises p-type silicon.

In Example 11, the solar cell in Examples 1, 2, or 3 is disclosed, wherein the solar cell is p-type solar cell with back emitter.

In Example 12, the solar cell in Examples 1, 2, or 3 is disclosed, wherein the emitter is a high ohm emitter.

In Example 13, the solar cell in Example 12 is disclosed, wherein the emitter minimizes recombination losses.

In Example 14, the cell in Example 12 is disclosed, wherein the emitter has an emitter saturation current of less than 80 fA/cm².

In Example 15, the solar cell in Examples 1, 2 or 3 is disclosed, wherein the p-type silicon substrate is doped.

In Example 16, the solar cell in Example 15 is disclosed, wherein the p-type silicon substrate is doped with boron.

In Example 17, the solar cell in Example 15 is disclosed, wherein the p-type silicon substrate is doped with gallium.

In Example 18, the solar cell in Example 17 is disclosed, wherein the gallium doped p-type silicon results in greater regularity compared to boron doped p-type silicon.

In Example 19, the solar cell of Example 17 is disclosed, wherein the gallium doped p-type silicon results in a longer minority carrier lifetime than a boron doped p-type silicon.

In Example 20, the solar cell of Example 17 is disclosed, wherein the gallium doped p-type silicon results in no lifetime degradation.

In Example 21, the solar cell of Examples 1, 2, or 3 is disclosed, wherein the emitter's saturation current is less than 40 fA/cm2.

In Example 22, the solar cell of Examples 1, 2, or 3 is disclosed, wherein the emitter is a selective emitter.

In Example 23, the solar cell of Example 22 is disclosed, wherein doping is performed on the emitter through the local addition of a doping medium.

In Example 24, the solar cell of Example 23 is disclosed, wherein the doping medium is a doping dielectric layer.

In Example 25, the solar cell of Example 23 is disclosed, wherein the doping medium a phosphorous doped silicon nitride.

In Example 26, the solar cell of claim 1, 2, or 3 is disclosed, further comprising a front contact on the front side of the silicon substrate.

In Example 27, the solar cell of Example 26 is disclosed, wherein the front contact comprises aluminum.

In Example 28, the solar cell of Example 27 is disclosed, wherein the front contact comprises silver.

In Example 29, the solar cell of Example 26 is disclosed, wherein the front contact comprises an aluminum/silver alloy.

In Example 30, the front contact of Example 26 is disclosed, wherein the front contact is formed into at least one line across the length of the solar cell.

In Example 31, the front contact of Example 26 is disclosed, wherein the front contact is formed into thin protrusions resembling fingers.

In Example 32, the front contact of Examples 25, 29, 30, or 31 is disclosed, wherein the front contact is printed.

In Example 33, the front contact of Example 32 is disclosed, wherein the front contact is screen printed.

In Example 34, the front contact of Example 32 is disclosed, wherein the front contact is fired.

In Example 35, the front contact of Examples 25, 29, 30, or 31 is disclosed, wherein the lengthwise portions, widthwise portions, or the fingers of the front contact have a width of 30-60 μm.

In Example 36, the front contact of Example 35 is disclosed, wherein the width of the fingers allows for minimal shadowing/shading of the silicon substrate.

In Example 37, the front contact of Examples 25, 29, 30, or 31 is disclosed, wherein portions of the silicon substrate are recessed to accommodate the front contact.

In Example 38, the front contact of Example 37 is disclosed, wherein the silicon substrate is recessed by etching.

In Example 39, the front contact of Example 37 is disclosed, wherein the silicon substrate is recessed by laser.

In Example 40, the front contact of Example 37 is disclosed, wherein the placement of the front contact in recessed portions of the silicon substrate decreases shadowing on the silicon substrate.

In Example 41, the front contact of Example 40 is disclosed, wherein the placement of the front contact in recessed portions of the silicon substrate increases efficiency.

In Example 42, the front contact of Example 25 is disclosed, wherein the front contact comprises a transparent coating oxide.

In Example 43, the front contact of Example 42 is disclosed, further comprising metal contacts on the front face of the transparent coating oxide.

In Example 44, the front contact of Example 43 is disclosed, wherein the metal contacts are a grid metal structure.

In Example 45, the front contact of Example 44 is disclosed, wherein the metal contacts are screen printed on the transparent coating oxide.

In Example 46, the front contact of Examples 44 or 45 is disclosed, wherein the metal contacts comprise silver.

In Example 47, the front contact of Examples 44 or 45 is disclosed, wherein the metal contacts comprise aluminum.

In Example 48, the front contact of Example 45 is disclosed, wherein the metal contacts are 30 μm-40 μm.

In Example 49, the front contact of Example 45 is disclosed, wherein the metal contacts provide cross-connectivity.

In Example 50, the front contact of Example 43 is disclosed, wherein the front contact is doped.

In Example 51, the front contact of Example 50 is disclosed, wherein the front contact is doped with a local addition of doping medium.

In Example 52, the front contact of Example 51 is disclosed, wherein the front contact is doped from a doping dielectric layer.

In Example 53, the front contact of Example 52 is disclosed, wherein the front contact does not require firing.

In Example 54, the front contact of Example 53 is disclosed, wherein the front contact is galvanized.

In Example 55, the front contact of Example 54 is disclosed, wherein the front contact comprises silver.

In Example 56, the front contact of Example 54 is disclosed, wherein the front contact comprises nickel.

In Example 57, the front contact of Example 54 is disclosed, wherein the front contact comprises copper.

Etching or Creating Contacts

In Example 58, the solar cell of Examples 1, 2, or 3 is disclosed, wherein the rear passivation layer has contact openings that are less than 1200 μm apart from one another.

In Example 59, the solar cell of Example 58 is disclosed, wherein the rear passivation layer has contact openings that are less than 500 μm apart from one another.

In Example 60, the solar cell of Example 59 is disclosed, wherein the rear passivation layer has contact openings that are less than 300 μm apart from one another.

In Example 61, the solar cell of Examples 58, 59, or 60 is disclosed, wherein the close proximity of the contact openings minimizes cross conduction.

In Example 62, the solar cell of Examples 58, 59, or 60 is disclosed, wherein the contact openings are created by removing portions of the rear passivation layer to permit contact between the emitter and the rear contact.

In Example 63, the solar cell of Examples 58, 59, or 60 is disclosed, wherein the contact openings are linear.

In Example 64, the solar cell of Examples 58, 59, or 60 is disclosed, wherein the contact openings are a matrix of dots.

In Example 65, the solar cell of Examples 58, 59, or 60 is disclosed, wherein the contact openings are created by laser etching.

In Example 66, the solar cell of Example 65 is disclosed, wherein the laser etching is performed with a green laser.

In Example 67, the solar cell of Example 65 is disclosed, wherein the laser etching is performed with a red laser.

In Example 68, the solar cell of Examples 66 or 67 is disclosed, wherein the laser etching results in increased temperatures of the corresponding portions of the emitter.

In Example 69, the solar cell of Example 68 is disclosed, wherein the higher emitter temperatures result in in-situ doping.

The Rear Contact/Benefits of Metallization

In Example 70, the solar cell of Examples 1, 2, or 3 is disclosed, wherein the rear contact is metal.

In Example 71, the solar cell of Example 70 is disclosed, wherein the rear contact comprises silver.

In Example 72, the solar cell of Example 70 is disclosed, wherein the rear contact comprises nickel.

In Example 73, the solar cell of Example 70 is disclosed, wherein the rear contact comprises metalized aluminum.

In Example 74, the solar cell of Example 70 is disclosed, wherein the rear contact is a full surface metal layer.

In Example 75, the solar cell of Example 74 is disclosed, wherein the full surface metal layer comprises silver.

In Example 76, the solar cell of Example 75 is disclosed, wherein the rear contact is capable of conducting current.

In Example 77, the solar cell of Example 76 is disclosed, wherein the thickness of the rear contact is less than 300 nm.

In Example 78, the solar cell of Example 77 is disclosed, wherein the thickness of the rear contact is less than 200 nm.

In Example 79, the solar cell of Example 78 is disclosed, wherein the thickness of the rear contact is less than 100 nm.

In Example 80, the solar cell of Example 74 is disclosed, wherein the metal layer creates an opaque surface.

In Example 81, the solar cell of Example 74 is disclosed, wherein the metal layer undergoes an annealing process.

In Example 82, the solar cell of Example 74, 80, or 81 is disclosed, wherein the metal layer is applied via sputtering.

In Example 83, the solar cell of Example 82 is disclosed, wherein the sputtered metal layer comprises silver.

In Example 84, the solar cell of Example 76 is disclosed, wherein the contact has a sheet resistance of 380 ohms per square.

In Example 85, the solar cell of Example 84 is disclosed, wherein the contact has a low series resistance.

In Example 86, the solar cell of Example 83 is disclosed, wherein the process of applying the contact via sputtering requires less silver than screen printing the silver contact.

In Example 87, the solar cell of Example 86 is disclosed, wherein the smaller volume of silver via sputtering improves cost-efficiency.

In Example 88, the solar cell of 87 is disclosed, wherein a typical screen-printed, silver, rear contact requires 100 mg of silver per wafer.

In Example 89, the solar cell of Example 88 is disclosed, wherein a 300 nm full-surface contact applied by sputtering requires only 75 mg.

In Example 90, the solar cell of Example 89 is disclosed, wherein the reduced silver consumption results in a change of cost of silver from 0.04 [symbol] per wafer to 0.01 [symbol] per wafer.

In Example 91, the solar cell of Example 74 is disclosed, wherein the metal contact comprises metalized aluminum.

In Example 92, the solar cell of Example 91 is disclosed, wherein the metal contact is applied by sputtering.

In Example 93, the solar cell of Examples 91 or 92 is disclosed, wherein a layer of nickel is plated on the rear side of the rear metal contact.

In Example 94, the solar cell of Example 93 is disclosed, wherein the rear contact, and any metal thereon, comprises nickel and/or aluminum.

In Example 95, the solar cell of Example 94 is disclosed, wherein the rear contact, and any metal thereon, contains no silver.

In Example 96, the solar cell of Example 95 is disclosed, wherein neither the rear contact, nor any metal thereon, are applied with screen printing.

In Example 97, the solar cell of Example 96 is disclosed, wherein the plated nickel on the rear of the metalized aluminum contact replaces the need for Ag screen printing.

In Example 98, the solar cell of Example 97 is disclosed, wherein the nickel coating is less expensive than a screen-printed silver coating.

In Example 99, the solar cell of Examples 1, 2, or 3 are disclosed, wherein all metal surfaces on the rear side of the solar cell are sufficiently thin that they can be applied via sputtering.

In Example 100, the solar cell of Example 99 is disclosed, wherein all metal surfaces on the rear side of the solar cell are applied via sputtering.

In Example 101, the solar cell of Examples 1, 2, or 3 is disclosed, wherein the solar cell is a monofacial solar cell.

In Example 102, the solar cell of Examples 1, 2, or 3 is disclosed, where the rear contact is a TCO.

In Example 103, the solar cell of Example 102 is disclosed, wherein the TCO is zinc oxide.

In Example 104, the solar cell of Example 102 is disclosed, wherein the TCO is covered with a metal layer.

In Example 105, the solar cell of Example 104 is disclosed, wherein the metal layer is applied via PVD.

In Example 106, the solar cell of Example 115 is disclosed, wherein the metal layer is applied via sputtering.

In Example 107, the solar cell of Example 77, 78, or 79 is disclosed, wherein the metal layer is applied via physical vapor deposition.

In Example 108, the solar cell of Example 83 is disclosed, wherein the silver rear contact is plated with a metal.

In Example 109, the solar cell of Example 108 is disclosed, wherein the plated metal is solderable.

In Example 110, the solar cell of Example 109 is disclosed, wherein the plated metal is nickel.

In Example 111, the solar cell of Examples 1, 2, or 3 is disclosed, wherein electrical connection to the rear contact and the front contact is achieved with wires.

In Example 112, the solar cell of Example 111 is disclosed, wherein the wires are soldered.

In Example 113, the solar cell in Examples 1, 2 or 3 is disclosed, wherein the rear contact comprises layers of aluminum and nickel.

In Example 114, the solar cell in Example 113 is disclosed, wherein the emitter is highly doped silicon.

TCO Coating With Potentially Bifacial Structure

In Example 115, the solar cell of Example 102 is disclosed, wherein the TCO is applied via PVD.

In Example 116, the solar cell of Example 102 is disclosed, wherein the TCO is applied via sputtering.

In Example 117, the solar cell of Examples 115 or 116 is disclosed, wherein a silver contact is printed on the rear face of said TCO.

In Example 118, the solar cell of Example 117 is disclosed, wherein the silver contact comprises a low-temperature paste.

In Example 119, the solar cell of Example 117 is disclosed, wherein the silver contact forms line contacts on the transparent coating oxide.

In Example 120, the solar cell of Example 102 is disclosed, wherein the solar cell is a bifacial solar cell.

In Example 121, the solar cell of Example 23 is disclosed, wherein the selective emitter results in reduced contact recombination.

In Example 122, the solar cell of Example 23 is disclosed, wherein the emitter is selectively doped through heat-activation of phosphorous.

In Example 123, the solar cell of Examples 1, 2, or 3 is disclosed, wherein the p-type silicon substrate has been doped with Gallium.

In Example 124, the solar cell of Example 73 is disclosed, wherein the metalized aluminum is applied in a sputtering procedure.

In Example 125, the solar cell of Examples 1, 2, or 3 is disclosed, wherein the rear contact comprises silver or aluminum.

In Example 126, the solar cell of Examples 1, 2, or 3 is disclosed, further comprising plating a solderable layer of nickel on the rear contact.

In Example 127, the solar cell of Examples 1, 2, or 3 is disclosed, further comprising sputtering a solderable layer of nickel on the rear contact.

In Example 128, the solar cell of Examples 1, 2, or 3 is disclosed, further comprising plating a solderable layer of tin on the rear contact.

In Example 129, the solar cell of Examples 1, 2, or 3 is disclosed, further comprising sputtering a solderable layer of tin on the rear contact.

In Example 130, the solar cell of Examples 1, 2, or 3 is disclosed, wherein the contact openings are dashed lines in the rear passivation layer.

In Example 131, the solar cell of Examples 1, 2, or 3 is disclosed, wherein the distance between the contact openings is less than 1200 μm.

In Example 132, the solar cell of Examples 1, 2, or 3 is disclosed, wherein the rear contact comprises a transparent conducting oxide.

In Example 133, the solar cell of Examples 1, 2, or 3 is disclosed, further comprising a screen-printed silver contact on the transparent conducting oxide.

In Example 134, A p-type passivated solar cell with back emitter is disclosed, said solar cell comprising:

a p-type silicon substrate with a minority carrier lifetime of greater than 500 microseconds;
a planar emitter on the rear side of the silicon substrate;
a passivation layer on a rear side of the emitter, the passivation layer having contact openings to permit contact between the emitter and a rear contact;
the rear contact on a rear side of the passivation layer, where the rear contact is applied via physical vapor deposition.

In Example 135, a method of manufacturing a p-type solar cell is disclosed, said method comprising:

selecting a p-type silicon substrate with a minority carrier lifetime of greater than 500 microseconds;
doping a rear face of the p-type silicon substrate with phosphorous;
applying a passivation layer to a rear face of the p-type silicon substrate;
creating contact openings in the passivation layer;
forming a rear contact applying at least one layer of silver or aluminum via sputtering or physical vapor deposition; and
applying a plated layer of nickel on the rear contact.

In Example 136, the solar cell of Examples 1, 2, or 3 is disclosed, wherein the contact openings are formed by laser etching with a green or red laser, and wherein said green or red laser causes locally increased temperatures in the passivation layer and results in in situ doping.

1. A p-type solar cell with passivated front and rear side, comprising:
a p-type silicon substrate with a minority carrier lifetime of greater than 500 microseconds;
a planar emitter on the rear side of the silicon substrate, the rear side on an opposite side of the silicon substrate relative to a light source, wherein the emitter has a sheet resistance of greater than 200 ohms/square;
a passivation layer on a rear side of the emitter, wherein the passivation layer further comprises contact openings to permit contact between the emitter and a rear contact;
and wherein the distance between contact openings is less than 1200 μm; and
the rear contact on a rear side of the passivation layer.

2. The solar cell of claim 1, wherein the planar emitter has a sheet resistance of greater than 250 Ohm/sq.

3. The solar cell of claim 1, wherein the contact openings in the passivation layer are less than 900 μm apart.

4. The solar cell of claim 1, wherein the p-type silicon substrate has been doped with Gallium.

5. The solar cell of claim 1, wherein the rear contact comprises silver or aluminum.

6. The solar cell of claim 1, wherein the rear contact comprises a transparent conducting oxide.

7. The solar cell of claim 1, further comprising a solderable layer of nickel on the rear contact.

8. (canceled)

9. The solar cell of claim 7, further comprising the solderable layer of nickel on the rear contact being applied via sputtering in order to maintain a thin thickness of the solderable layer of nickel.

10. The solar cell of claim 1, further comprising a solderable layer of tin on the rear contact.

11. (canceled)

12. The solar cell of claim 10, further comprising the solderable layer of tin on the rear contact being applied via sputtering in order to maintain a thin thickness of the solderable layer of tin.

13. The solar cell of claim 1, wherein the contact openings are linear.

14. The solar cell of claim 1, wherein the contact openings are a matrix of dots.

15. The solar cell of claim 1, wherein the contact openings are dashed lines in the rear passivation layer.

16. The solar cell of claim 1, wherein the contact openings are formed by laser etching with a green or red laser, and wherein said green or red laser causes locally increased temperatures in the passivation layer and results in in situ doping.

17. A method of manufacturing a p-type solar cell, comprising:
selecting a p-type silicon substrate with a minority carrier lifetime of greater than 500 microseconds;
doping a rear face of the p-type silicon substrate with phosphorous wherein the rear face is on an opposite face of the silicon substrate relative to a light source;
applying a passivation layer to the rear face of the p-type silicon substrate;
creating contact openings in the passivation layer;
forming a rear contact by applying silver, aluminum, or a transparent conductive oxide; and
applying a solderable layer of metal on the rear face of the solar cell via plating or sputtering.

18. The method of claim 17, further comprising the solderable layer of metal comprising nickel.

19. The method of claim 17, further comprising the solderable layer of metal comprising tin.

20. The method of claim 17, wherein the contact openings in the passivation layer are less than 900 μm apart.

21. A p-type solar cell with passivated front and rear side, comprising:
a p-type silicon substrate with a minority carrier lifetime of greater than 500 microseconds;
a planar emitter on the rear side of the silicon substrate, wherein the planar emitter is not textured and the rear side is on an opposite side of the silicon substrate relative to a light source, wherein the emitter has a sheet resistance of greater than 200 ohms/square;
a passivation layer on a rear side of the emitter, wherein the passivation layer further comprises contact openings to permit contact between the emitter and a rear contact;
wherein the distance between contact openings is less than 1200 μm; and
the rear contact on a rear side of the passivation layer.

22. The solar cell of claim 21, wherein the planar emitter is configured to minimize interface states with the passivation layer and contact openings.
